(19) United States
(12) Patent Application Publication
(10) Pub. No.: US 2023/0152611 A1
(43) Pub. Date: May 18, 2023

(54) WAFER STACK WITH MgO DIRECTLY ON INSULATING LAYER

(71) Applicant: PSIQUANTUM CORP., Palo Alto, CA (US)

(72) Inventors: Mark THOMPSON, Palo Alto, CA (US); Ranida WONGPIYA, Palo Alto, CA (US); Chia-Ming CHANG, Palo Alto, CA (US)

(21) Appl. No.: 17/995,340

(22) PCT Filed: Apr. 1, 2021
(86) PCT No.: PCT/US2021/025342

§ 371 Date: Oct. 3, 2022

Related U.S. Application Data
(60) Provisional application No. 63/003,800, filed on Apr. 1, 2020.

(51) Int. Cl. G02F 1/035; G02F 1/21; G02F 1/225; C23C 14/08; C23C 14/02; C23C 14/30; C23C 14/22; C23C 14/06

(52) U.S. Cl. CPC G02F 1/035; G02F 1/212; G02F 1/225; C23C 14/081; C23C 14/024; C23C 14/30; C23C 14/221; C23C 14/06; C23C 14/021; C23C 14/083; C23C 14/08

(57) ABSTRACT

A method includes depositing a crystalline magnesium oxide (MgO) seed layer directly on an amorphous insulating cladding layer by a physical vapor deposition (PVD) process, and depositing a crystalline electro-optic layer directly on the crystalline MgO seed layer.

### TECHNICAL FIELD

Embodiments herein relate generally to electro-optic devices, such as phase shifters and switches, and more specifically to wafer stacks for inclusion within electro-optic devices.

### BACKGROUND

Wafer stacks are utilized to construct a wide variety of high-performance computation components such as electro-optic (EO) modulators and switches. Effective wafer stack construction generally requires extremely high precision and layer uniformity, with accuracies of up to single-atom resolution. Further, wafer stack construction at a desired level of fidelity may be an expensive multistep process. Accordingly, improvements in the field are desired.

### SUMMARY

Some embodiments described herein provide a method which includes depositing a crystalline magnesium oxide (MgO) seed layer directly on an amorphous insulating cladding layer by a physical vapor deposition (PVD) process, and depositing a crystalline electro-optic layer directly on the crystalline MgO seed layer.

Some embodiments described herein provide a device, comprising a crystalline magnesium oxide (MgO) seed layer located directly on an amorphous insulating cladding layer, and a crystalline electro-optic layer located directly on the crystalline MgO seed layer via a second PVD process.

This Summary is intended to provide a brief overview of some of the subject matter described in this document. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the Figures.

FIG. 1 is a simplified schematic diagram illustrating an optical switch according to some embodiments;

FIG. 2 is a schematic diagram of a wafer stack comprising stacked layers, according to some embodiments.

FIG. 3 is a simplified schematic diagram illustrating a cross section of a wafer stack, according to some embodiments;

FIG. 4 is a simplified schematic diagram illustrating a cross section of a wafer stack including a waveguide embedded within the SiO₂ layer, according to some embodiments;

FIG. 5 is a simplified schematic diagram illustrating a cross section of a ridge waveguide structure, according to some embodiments;

FIG. 6 is a simplified schematic diagram illustrating a cross section of an electro-photonic phase shifter, according to some embodiments.

FIG. 7 is a simplified schematic diagram illustrating a cross section of a waveguide structure incorporating high-K electrodes placed opposite the waveguide ridge, according to some embodiments;

FIG. 8 is a simplified schematic diagram illustrating a cross section of a waveguide structure incorporating high-K electrodes placed opposite the waveguide ridge with penetrating leads, according to some embodiments;

FIG. 9 is a simplified schematic diagram illustrating a cross section of a waveguide structure incorporating high-K electrodes placed on the same side as the waveguide ridge, according to some embodiments;

FIG. 10 is a simplified schematic diagram illustrating across section of a waveguide structure incorporating high-K electrodes and exhibiting a sandwich structure, according to some embodiments;

FIG. 11 is a simplified schematic diagram illustrating across section of a vertical waveguide structure incorporating high-K materials, according to some embodiments;

FIG. 12 is a simplified schematic diagram illustrating across section of a waveguide structure with the electrodes in-line with the waveguide structure, according to some embodiments;

FIG. 13 is a simplified schematic diagram illustrating a cross section of a waveguide structure with electrodes exhibiting ridge-like profiles, according to some embodiments; and

FIG. 14 is a simplified schematic diagram showing a top view of a waveguide structure, according to some embodiments.

While the features described herein may be susceptible to various modifications and alternative forms, specific embodiments thereof are shown by way of example in the drawings and are herein described in detail. It should be understood, however, that the drawings and detailed description thereto are not intended to be limiting to the particular form disclosed, but on the contrary, the intention is to cover all modifications, equivalents and alternatives falling within the spirit and scope of the subject matter as defined by the appended claims.

### DETAILED DESCRIPTION

Reference will now be made in detail to embodiments, examples of which are illustrated in the accompanying drawings. In the following detailed description, numerous specific details are set forth in order to provide a thorough understanding of the various described embodiments. However, it will be apparent to one of ordinary skill in the art that the various described embodiments may be practiced without these specific details. In other instances, well-known methods, procedures, components, circuits, and networks have not been described in detail so as not to unnecessarily obscure aspects of the embodiments.

It will also be understood that, although the terms first, second, etc. are, in some instances, used herein to describe various elements, these elements should not be limited by these terms. These terms are used only to distinguish one element from another. For example, a first electrode layer could be termed a second electrode layer, and, similarly, a second electrode layer could be termed a first electrode layer, without departing from the scope of the various described embodiments. The first electrode layer and the second electrode layer are both electrode layers, but they are not the same electrode layer.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

### Electro-Optical Devices

Embodiments of the present invention are directed to a wafer stack and methods for constructing wafer stacks, for use in fabricating components of optical systems. Merely by way of example, embodiments of the present invention are provided in the context of integrated optical systems that include active optical (e.g., electro-optical) devices, but the invention is not limited to this example and has wide applicability to a variety of optical and optoelectronic systems.

According to some embodiments, the active photonic devices described herein utilize electro-optic effects, such as free carrier induced refractive index variation in semiconductors, the Pockel's effect, and/or the DC Kerr effect to implement modulation and/or switching of optical signals. Thus, embodiments of the present invention are applicable to both modulators, in which the transmitted light is modulated either ON or OFF, or light is modulated with a partial change in transmission percentage, as well as optical switches, in which the transmitted light is output on a first output (e.g., waveguide) or a second output (e.g., waveguide) or an optical switch with more than two outputs, as well as more than one input. Thus, embodiments of the present invention are applicable to a variety of designs including an M(input)×N(output) systems that utilize the methods, devices, and techniques discussed herein. Some embodiments also relate to electro-optic phase shifter devices, also referred to herein as phase adjustment sections, that may be employed within switches or modulators.

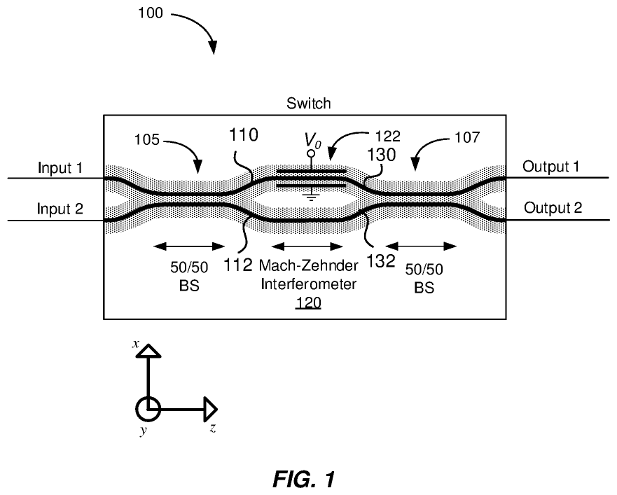

FIG. 1 is a simplified schematic diagram illustrating an optical switch according to an embodiment of the present invention. Referring to FIG. 1, switch 100 includes two inputs: Input 1 and Input 2 as well as two outputs: Output 1 and Output 2. As an example, the inputs and outputs of switch 100 can be implemented as optical waveguides operable to support single mode or multimode optical beams. As an example, switch 100 can be implemented as a Mach-Zehnder interferometer integrated with a set of 50/50 beam splitters 105 and 107, respectively. As illustrated in FIG. 1, Input 1 and Input 2 are optically coupled to a first 50/50 beam splitter 105, also referred to as a directional coupler, which receives light from the Input 1 or Input 2 and, through evanescent coupling in the 50/50 beam splitter, directs 50% of the input light from Input 1 into waveguide 110 and 50% of the input light from Input 1 into waveguide 112. Concurrently, first 50/50 beam splitter 105 directs 50% of the input light from Input 2 into waveguide 110 and 50% of the input light from Input 2 into waveguide 112. Considering only input light from Input 1, the input light is split evenly between waveguides 110 and 112.

Mach-Zehnder interferometer 120 includes phase adjustment section 122. Voltage V₀ can be applied across the waveguide in phase adjustment section 122 such that it can have an index of refraction in phase adjustment section 122 that is controllably varied. Because light in waveguides 110 and 112 still have a well-defined phase relationship (e.g., they may be in-phase, 180° out-of-phase, etc.) after propagation through the first 50/50 beam splitter 105, phase adjustment in phase adjustment section 122 can introduce a predetermined phase difference between the light propagating in waveguides 130 and 132. As will be evident to one of skill in the art, the phase relationship between the light propagating in waveguides 130 and 132 can result in output light being present at Output 1 (e.g., light beams are in-phase) or Output 2 (e.g., light beams are out of phase), thereby providing switch functionality as light is directed to Output 1 or Output 2 as a function of the voltage V₀ applied at the phase adjustments section 122. Although a single active arm is illustrated in FIG. 1, it will be appreciated that both arms of the Mach-Zehnder interferometer can include phase adjustment sections.

As illustrated in FIG. 1, electro-optic switch technologies, in comparison to all-optical switch technologies, utilize the application of the electrical bias (e.g., V₀ in FIG. 1) across the active region of the switch to produce optical variation. The electric field and/or current that results from application of this voltage bias results in changes in one or more optical properties of the active region, such as the index of refraction or absorbance.

Although a Mach-Zehnder interferometer implementation is illustrated in FIG. 1, embodiments of the present invention are not limited to this particular switch architecture and other phase adjustment devices are included within the scope of the present invention, including ring resonator designs, Mach-Zehnder modulators, generalized Mach-Zehnder modulators, and the like. One of ordinary skill in the art would recognize many variations, modifications, and alternatives.

### Wafer Stack Design

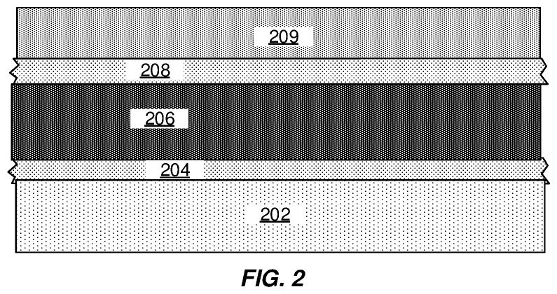

The optical switch illustrated in FIG. 1 may include a waveguide structure that has been patterned from a wafer stack. FIG. 2 illustrates an example wafer stack that may be produced according to embodiments described herein, which may be etched to produce the waveguide structure. FIG. 2 illustrates a cross section of a wafer stack, according to some embodiments. As illustrated, a first insulating substrate layer (202) may be disposed beneath a seed layer (204), which is disposed beneath an electro-optic layer (206). In some embodiments, the wafer stack may further include an (optional) electrode layer (208) disposed above the electro-optic layer, and an (optional) second insulating substrate layer (209) disposed above the electrode layer (208). The second insulating substrate layer (209) may be disposed directly above the electro-optic layer, if the electrode layer is not present, in some embodiments. In other words, while FIG. 2 illustrates that each of the five layers 202-209 are present, any one or more of these layers may be absent, in various embodiments. The wafer stack may be of various types depending on the specific fabrication method to be employed, and the electrode layer, and second substrate layer may be optionally present or not present, as desired. One or more of the layers illustrated in FIG. 2 may be chemically etched to produce an electro-optical component.

Each of the layers of the wafer stack may be of any of a variety of types of materials. For example, the electrode layer 208 may be composed of a conducting material such as a metal, or alternatively it may be composed of a semiconductor material or a dielectric material to form dielectric electrodes which will be described in more detail below. In various embodiments, the electrode layer is composed of one of gallium arsenide (GaAs), an aluminum gallium arsenide (AlGaAs)/GaAs heterostructure, an indium gallium arsenide (InGaAs)/GaAs heterostructure, zinc oxide (ZnO), zinc sulfide (ZnS), indium oxide (InO), doped silicon, strontium titanate (STO), doped STO, barium titanate (BTO), barium strontium titanate (BST), hafnium oxide, lithium niobate, zirconium oxide, titanium oxide, graphene oxide, tantalum oxide, lead zirconium titanate (PZT), lead lanthanum zirconium titanate (PLZT), strontium barium niobate (SBN), aluminum oxide, doped variants or solid solutions thereof, or a two-dimensional electron gas layer (e.g., a layer having less than few monolayer thickness that provides a two-dimensional electron gas). For embodiments where the electrode layer is composed of doped STO, the STO may be either niobium doped or lanthanum doped, or may contain vacancies, according to various embodiments.

In various embodiments, the electro-optic layer 206 is composed of one of strontium titanate (STO), barium titanate (BTO), barium strontium titanate (BST), hafnium oxide, lithium niobate, zirconium oxide, titanium oxide, graphene oxide, tantalum oxide, lead zirconium titanate (PZT), lead lanthanum zirconium titanate (PLZT), strontium barium niobate (SBN), aluminum oxide, aluminum oxide, or doped variants or solid solutions thereof. The electro-optic layer may be composed of a transparent material having an index of refraction that is larger than an index of refraction of the first and second insulating substrate layers, in some embodiments. The electro-optic layer may be composed of a ferroelectric material.

The first and/or second insulating substrate layers (202, 209) may each be of any of a variety of types of insulating materials. For example, the insulating substrate layers may be composed silicon oxide, silicon nitride, tantalum oxide (such as SiO₂, SiN (e.g., Si₃N₄), or TaO₂ or non-stoichiometric versions thereof), or silicon oxynitride, among other possibilities. The first and/or second insulating substrate layer may be cladding layers. In exemplary embodiments, the seed layer 204 is composed of magnesium oxide (MgO), such as a crystalline MgO layer.

Wafer Stack with MgO Directly on Amorphous Layer

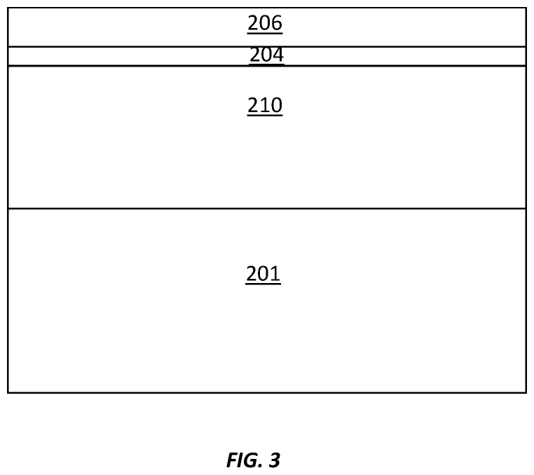

Referring to FIG. 3, present embodiments provide a wafer stack design in which a crystalline magnesium oxide (MgO) seed layer 204 is grown directly on an amorphous insulating layer 210, such as silicon oxide, silicon nitride, tantalum oxide (such as SiO₂, SiN (e.g., Si₃N₄) or TaO₂ or non-stoichiometric versions thereof), or silicon oxynitride, or another type of insulating oxide or nitride layer, or a polymer layer among other possibilities. In one embodiment, the amorphous insulating layer 210 may comprise the first insulating substrate layer 202 described above with respect to FIG. 2.

As used herein, the term “amorphous” is intended to refer to any solid of a broad variety of amorphous or non-crystalline solids, wherein the solid lacks the long-range order that is characteristic of a crystal. Types of amorphous solids may include glasses or polymers, which may be in a thin film form or in a bulk substrate form.

As shown in FIG. 3, the amorphous insulating layer 210 may be a thin film formed on an underlying substrate 201, such as a silicon wafer, or the amorphous insulating layer 210 may comprise a free standing substrate, such as a glass substrate. For example, the amorphous insulating layer 210 may have a thickness of 1 to 10 microns. However, other thicknesses may also be used. In one embodiment, the amorphous insulating layer 210 may comprise a cladding layer of an electro-optical device, such as an electo-optical switch or modulator. In this embodiment, the underlying substrate 201, such as a silicon wafer, may be removed after formation of one or more overlying layers of the wafer stack. The substrate 201 may be removed by grinding, polishing, selective etching or by selectively etching away a sacrificial release layer located between the substrate 201 and the amorphous insulating layer 210. Alternatively, the substrate 201 may be retained in the final electro-optic device.

The crystalline MgO seed layer 204 may be composed of single crystalline or polycrystalline MgO. The MgO seed layer 204 may be grown directly on the amorphous insulating layer 210 by physical vapor deposition (PVD). For example, a crystalline MgO may be grown directly on an amorphous silicon nitride or silicon oxide layer by PVD methods, such as ion beam-assisted deposition or electron beam evaporation (see for example, R. Brewer, et. al., Applied Physics Letters, 80 (18) 3388 (2002); S. Wang, et. al., Applied Physics Letters 109, 191603 (2016); J. S. Lee, et. al., Thin Solid Films 354, (1-2), (1999), Pages 82-86, all incorporated by reference in their entirety). Other PVD methods, such as sputtering or molecular beam epitaxy may also be used. The MgO seed layer may have a thickness of 1 to 20 nm. However, other thicknesses may also be used.

A crystalline (e.g., single crystal or polycrystalline) electro-optic layer 206 is then grown on the crystalline MgO seed layer 204. Since the MgO seed layer 204 is crystalline, it may be used as a template to grow a crystalline electro-optic layer 206. In one embodiment, the electro-optic layer 206 may comprise a ferroelectric electro-optic layer, such as a barium titanate (BTO) layer 206. The electro-optic layer 206 may have a thickness of 50 to 500 nm. However, other thicknesses may also be used.

Embodiments of the present disclosure provide an improved wafer stack fabrication method by growing a thin crystalline MgO seed layer directly on an amorphous layer and subsequently growing a crystalline electro-optic layer on the seed layer. In one embodiment, this results in a crystalline ferroelectric on amorphous insulator material stack. Advantageously, the embodiment stack design may avoid the need to perform wafer bonding and film transfer to achieve the ferroelectric-on-insulator structure, which simplifies the process and reduces its cost.

In contrast, in some prior art wafer stacks, the crystalline seed layer is grown directly on a crystalline silicon substrate. This requires subsequent removal of the silicon substrate and bonding a separate handle substrate containing an insulating cladding layer to the seed layer or to the electro-optic layer if the seed layer is also removed with the crystalline silicon substrate. The handle substrate is then separated from the insulating cladding layer, leaving the insulating cladding layer bonded directly or indirectly to the electro-optic layer. This complicates the fabrication process.

In some embodiments, a fully physical vapor deposition (PVD)-based process is utilized to grow a high-quality crystalline PVD electro-optic layer on a high quality crystalline PVD MgO seed layer. Advantageously, the thin MgO seed layer may have a minimal impact on the optical performance of the thicker electro-optic (e.g., BTO) layer. The embodiment wafer stack structure may facilitate the fabrication of electro-optic devices within a single process flow by utilizing standard complementary metal-oxide-semiconductor (CMOS) fabrication tools, and the final structure may be produced without disrupting the vacuum environment during the process flow (e.g., all layers may be deposited and patterned in a vacuum cluster tool without breaking vacuum). In one embodiment, the wafer stack may be produced without utilizing molecular beam epitaxy (MBE) to form the seed layer.

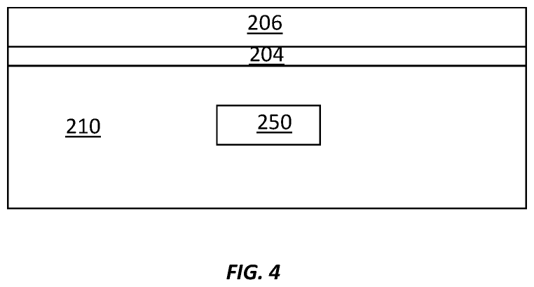

FIG. 4 shows an alternative embodiment of a wafer stack including a waveguide 250 embedded within the amorphous insulating layer 210, such as a cladding layer. The waveguide 250 may extend in the direction in and out of the plane of the drawing of FIG. 4. The waveguide 250 may comprise any suitable waveguiding material, such as silicon nitride or silicon.

In one embodiment, the waveguide 250 may be formed by a damascene process which includes forming a lower portion of the amorphous insulating layer 210, forming a trench in the lower portion of the amorphous insulating layer 210 by photolithography and etching, filling the trench with the material of the waveguide 250 and planarizing the waveguiding material using chemical mechanical polishing or etch back with the top surface of the lower portion of the amorphous insulating layer 210. An upper portion of the amorphous insulating layer 210 is then formed over the waveguide 250 and the lower portion of the amorphous insulating material 210.

In another embodiment, the waveguide 250 may be formed by an etching process which includes forming a lower portion of the amorphous insulating layer 210, forming a waveguide material layer over the lower portion of the amorphous insulating layer 210, patterning the waveguide material layer into the waveguide 250 by photolithography and etching, and forming the upper portion of the amorphous insulating layer 210 over the waveguide 250 and the lower portion of the amorphous insulating material 210. The upper portion of the amorphous insulating layer 210 may be 5 to 500 nanometers thick.

The crystalline MgO seed layer 204 and the electro-optic layer 206 are then formed over the upper portion of the amorphous insulating layer 210 and the waveguide 250. Therefore, the crystalline MgO seed layer 204 may be vertically separated from the waveguide 250 by a distance of 5 to 500 nm (e.g., by the thickness of the upper portion of the amorphous insulating layer 210).

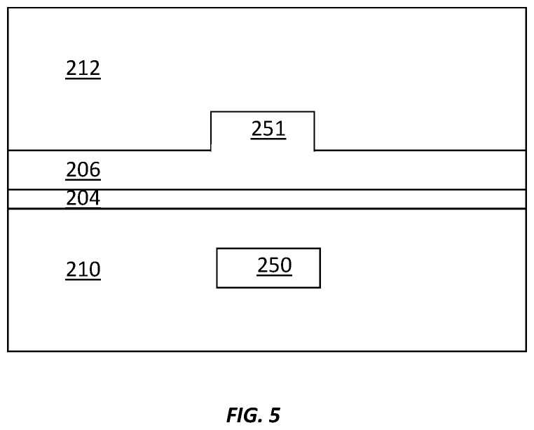

FIG. 5 is a simplified schematic diagram illustrating a cross section of a ridge waveguide structure, according to an embodiment. In the embodiment of FIG. 5, after forming the structure of FIG. 4, a patterned mask is formed over the electro-optic layer 206 by photolithography, followed by etching or ion milling the unmasked portioned of the electro-optic layer 206 form the a ridge portion 251. The second insulating cladding layer 212, such as silicon oxide, silicon nitride, etc., is formed over the ridge portion 251 of the electro-optic layer 206.

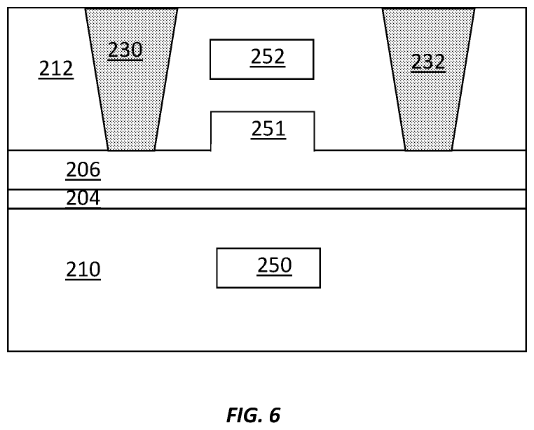

FIG. 6 is a simplified schematic diagram illustrating a cross section of an electro-photonic phase shifter, according to some embodiments. In the embodiment of FIG. 6, after forming the structure of FIG. 5, an optional second waveguide 252 may be embedded in the second cladding layer 212 over the ridge portion 251 of the electro-optic layer 206. The second waveguide 252 may be formed in the second cladding layer 212 using either the damascene process or the etching process described above for forming the first waveguide 252. In should be noted that the first waveguide 250 and/or the second waveguide 252 may be omitted. The electrical contacts including leads 230 and 232 are then formed through the second cladding layer 212. The leads 230 and 232 may be formed by forming via openings in the second cladding layer 212 by photolithography and etching, followed by depositing an electrically conductive material (e.g., a metal, such as Al, Cu, W, Ti, or alloys thereof, a conductive metal nitride (e.g., TiN, WN, etc.), silicide (e.g., WSi, TiSi, etc.), or heavily doped semiconductor material (e.g., polysilicon)) in the via openings. The conductive material is then planarized with the top surface of the second cladding layer 212 by chemical mechanical polishing or etch back.

In an optional embodiment, conductive, semiconductor or dielectric electrodes may be formed in contact with the leads 230 and/or the electro-optic layer 206, as will be described below.

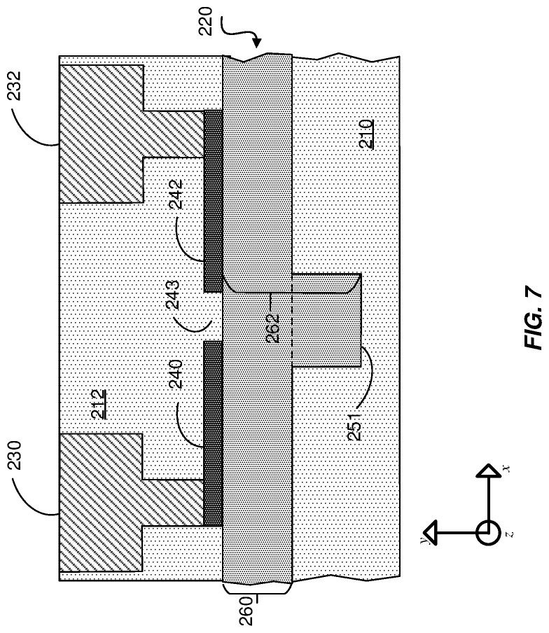

FIGS. 7-13 are simplified cross-section diagrams illustrating various alternative architectures for a photonic phase shifter which may be fabricating using the wafer stack described above, according to various embodiments. In one embodiment, the photonic phase shifter may comprise the includes phase adjustment section 122 of the Mach-Zehnder interferometer 120 illustrated in FIG. 1.

The architectures shown in FIGS. 7-13 are schematic illustrations, and are not necessarily drawn to scale. The thin MgO seed layer 204 described above may be located between the first cladding layer 210, 310, 410, 510, 610, 710, and 810 and the waveguide slab/ridge layer (e.g., BTO layer) 220, 320, 420, 520, and 920 in FIGS. 7-13. However, the MgO seed layer is not shown in FIGS. 7-13 due to its low thickness.

While the architectures shown in FIG. 7-13 differ in several important design features, they also share some features in common. For example, as described in greater detail below, each of FIGS. 7-13 exhibit two electrical contacts, and each electrical contact includes a lead (230, 330, 430, 530, 630, 730, and 830, as well as 232, 332, 432, 532, 632, 732, and 832) connected to an electrode (240, 340, 440, 540, 640, 740, and 840, as well as 242, 342, 442, 542, 642, 742, and 842). It is noted that, as used herein, the term “electrode” refers to a device component that directly couples to the waveguide structure (e.g., to alter the voltage drop across the waveguide structure and actuate a photonic switch). Further, the term “lead” refers to a backend structure that couples the electrodes to other components of the device (e.g., the leads may couple the electrodes to a controllable voltage source), but the leads are isolated from and do not directly couple to the waveguide structure. In some embodiments, the leads may be composed of a metal (e.g., copper, gold, etc.), or alternatively, a semiconductor material.

The electrodes are configured to extend in close proximity to the location of the optical mode in the waveguide, and the photonic phase shifter is configured such that a controllable voltage difference may be introduced across the two electrodes (e.g., dielectric electrodes in some embodiments), to alter the accumulated phase of a photonic mode travelling through the waveguide. For example, the electrodes may be coupled, via the leads, to a voltage source that imposes the controllable voltage difference.

In some embodiments, the electrodes may be composed of a high-κ dielectric material with a large dielectric constant, such that the electrodes have a larger dielectric constant than the material of the waveguide and/or the slab layer. As used herein, a is used to represent the dielectric constant, which refers to the real component of the relative permittivity. κ=Re(εᵣ)=Re(ε/ε₀), where εᵣ is the complex-valued relative permittivity, ε is the absolute permittivity of the material, and ε₀ is the permittivity free space. It is noted for clarity that the imaginary component of εᵣ is related to the conductivity of the material, whereas the real component, κ, is related to the dielectric polarizability of the material.

The dielectric constant of a material may have a different value in the presence of a direct current (DC) voltage compared to an (AC) voltage, and the dielectric constant of the material in an AC voltage may be a function of frequency, κ(ω). Accordingly, in some embodiments, when selecting a material for the electrodes, the slab layer, and/or the ridge portion, the dielectric constant of the material may be considered at the operating frequency of the photonic phase shifter.

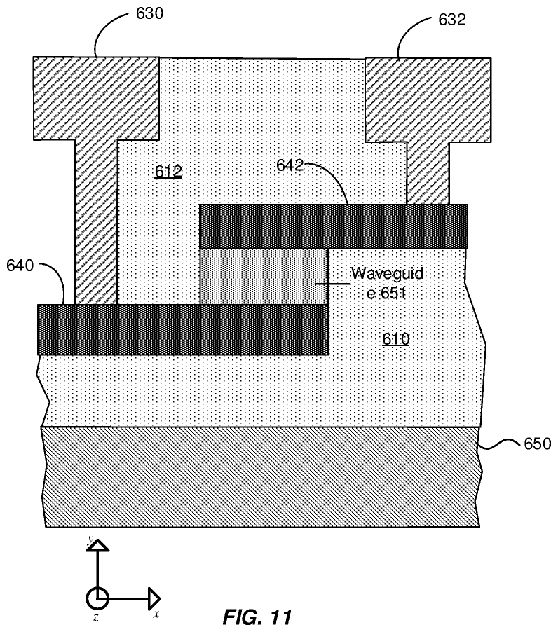

The electrodes may be composed of a material with a higher dielectric constant along the direction separating the first and second electrodes (e.g., the x-direction in FIGS. 7-10 and 12-13, or the y-direction in FIG. 11) than the first material of the slab layer. For example, in anisotropic media, the permittivity tensor E may be expressed by the following matrix which relates the electric field E to the electric displacement D.

$$[ \begin{matrix}{D}_{x} ( \overline{r} ) \\ {D}_{y} ( \overline{r} ) \\ {D}_{z} ( \overline{r} )\end{matrix} ] = [ \begin{matrix}{ε}_{xx} & {ε}_{xy} & {ε}_{xz} \\ {ε}_{yx} & {ε}_{yy} & {ε}_{yz} \\ {ε}_{zx} & {ε}_{zy} & {ε}_{zz}\end{matrix} ] [ \begin{matrix}{E}_{x} ( \overline{r} ) \\ {E}_{y} ( \overline{r} ) \\ {E}_{z} ( \overline{r} )\end{matrix} ] , \qquad ( 1 )$$

where the components εₓₓ, ε_{xy}, etc., denote the individual components of the permittivity tensor. In some embodiments, the material of the first and second electrodes may be selected such that the diagonal component of the permittivity tensor along the direction separating the electrodes is larger than the corresponding diagonal component of the permittivity tensor of the material of the slab layer and/or the ridge portion.

TABLE 1
χ⁽³⁾, Refractive Index, and Dielectric Constant Values
for Various Materials

| | | Refractive Index | |
|---|---|---|---|
| Material | χ⁽³⁾ (m²/W) | (at 1.55 μm) | Dielectric Constant |
| Si | 2.2 × 10⁻¹⁸ | ~3.5 | 11.7 |
| Si₃N₄ | 2 × 10⁻¹⁹ | 2 | 7-8 |
| | 1.6 × 10⁻¹⁸ | 2.5 | |
| | 2 × 10⁻¹⁸ | 2.7 | |
| Ta₂O₅ | 1 × 10⁻¹⁸-4 × 10⁻¹⁸ | 2.08 | 25-50 |
| TiO₂ | 5 × 10⁻¹⁸-6 × 10⁻¹⁷ | 2.27-2.6 | 10-85 |
| Graphene | 4.5 × 10⁻¹⁴ | 2.2 ( at 1.2 μm) | 2-50 |
| Oxide | | | |
| STO | | ~2.3 | 10,000-24,000 (below |
| | | | 10K) |
| BTO | r42 > 150 pm/V | ~2.3 | 150-200 (below 10K) |
| | | | 1000 to 3000 (at 300K) |

Table 1 illustrates the Kerr coefficient χ⁽³⁾, refractive index, and dielectric constant values for a variety of materials. As shown in Table 1, STO has an extremely high dielectric constant for temperatures below 10K, such that STO may be a desirable material to use for the electrodes, while BTO may be used for the slab layer and/or ridge portion of the waveguide, in some embodiments.

As illustrated, the architectures shown in each of FIGS. 7-13 exhibit a photonic device comprising first and second cladding layers. For example, the regions marked 210, 310, 410, 510, 610, 710, and 810 represent first cladding layers on one side of the waveguide, while the regions marked 212, 312, 412, 512, 612, 712, and 812 represent second cladding layers on the other side of the waveguide. In some embodiments, the first and/or second cladding layer is an amorphous insulating layer of a wafer stack, such as layers 202 and/or 209 illustrated in FIG. 2 or the amorphous insulating layer illustrated in FIG. 3. It is noted that the terms “first” and “second” are meant simply to distinguish between the two cladding layers, and, for example, the term “first cladding layer” may refer to the cladding layer on either side of the waveguide. The index of refraction of the first and second cladding layers may be lower than the index of refraction of the waveguide structure, in some embodiments.

FIGS. 7-13 further exhibit a first electrical contact including a first lead (230, 330, 430, 530, 630, 730, and 830) coupled to a first electrode (240, 340, 440, 540, 640, 740, and 840) and a second electrical contact including a second lead (232, 332, 432, 532, 632, 732, and 842) coupled to a second electrode (242, 342, 442, 542, 642, 742, and 842). The first and second leads may be composed of a conducting material such as a metal, or alternatively they may be composed of a semiconductor material. In various embodiments, the first electrode and the second electrode are composed of one or more of gallium arsenide (GaAs), an aluminum gallium arsenide (AlGaAs)/GaAs heterostructure, an indium gallium arsenide (InGaAs)/GaAs heterostructure, zinc oxide (ZnO), zinc sulfide (ZnS), indium oxide (InO), doped silicon, strontium titanate (STO), doped STO, barium titanate (BTO), barium strontium titanate (BST), hafnium oxide, lithium niobate, zirconium oxide, titanium oxide, graphene oxide, tantalum oxide, lead zirconium titanate (PZT), lead lanthanum zirconium titanate (PLZT), strontium barium niobate (SBN), aluminum oxide, aluminum oxide, doped variants or solid solutions thereof, or a two-dimensional electron gas layer. For embodiments where the first and second electrodes are composed of doped STO, the STO may be either niobium doped or lanthanum doped, or contain vacancies, according to various embodiments.

FIGS. 7-13 illustrate a waveguide structure including a slab layer (220, 320, 420, and 520, 651, 754, and 851) comprising a first material, wherein the slab layer is coupled to the first electrode of the first electrical contact and the second electrode of the second electrical contact. In some embodiments, the waveguide structure further includes a ridge portion (251, 351, 451, and 551) composed of the first material (or a different material) and coupled to the slab layer, where the ridge portion is disposed between the first electrical contact and the second electrical contact. In various embodiments, the first material is one of strontium titanate (STO), barium titanate (BTO), barium strontium titanate (BST), hafnium oxide, lithium niobate, zirconium oxide, titanium oxide, graphene oxide, tantalum oxide, lead zirconium titanate (PZT), lead lanthanum zirconium titanate (PLZT), strontium barium niobate (SBN), aluminum oxide, aluminum oxide, or doped variants or solid solutions thereof. The first material may be a transparent material having an index of refraction that is larger than an index of refraction of the first and second cladding layers, in some embodiments.

In some embodiments, a second material composing the first and second electrodes may be selected based on the first material composing the slab layer and/or the waveguide structure. For example, the second material may be selected such that the second material has a larger dielectric constant than the dielectric constant of the first material. As one example, if the first material is BTO, the second material may be selected to be STO, which has a larger dielectric constant than BTO at the cryogenic temperatures (e.g., 4K) at which the photonic device is intended to operate. Advantageously, the large dielectric constant of the electrodes may enable the electrodes to be placed in closer proximity to the waveguide compared to metallic electrodes, for a given acceptable level of loss from the waveguide into the electrodes. For example, the high conductivity of a metallic electrode will result in a larger degree of photon absorption (i.e., loss) from the waveguide compared to the absorption of an electrode at the same separation from the waveguide. Accordingly, the electrodes may be placed in closer proximity to the waveguide than metallic electrodes for a given loss tolerance. The high dielectric constant of the electrodes corresponds to a high polarizability of the dielectric material, which in turn results in an energy-efficient control mechanism to adjust the electric field within the waveguide structure.

In some embodiments, the materials used for the electrodes, and the waveguide structure may be selected based on their effective dielectric constants. For example, while the dielectric constant (or the dielectric tensor for anisotropic materials) of a material is an intrinsic material property, the effective dielectric constant of a structure is proportional to its dielectric constant but also depends on the shape and dimensions of the structure. In these embodiments, the material used for the first and second electrodes may be selected such that the effective dielectric constant of the first and second electrodes is greater than an effective dielectric constant of the waveguide structure.

In some embodiments, the first electric contact and the second electrical contact are configured to generate an electric field along one or more directions. e.g., along the x-direction in the waveguide structure, and the waveguide structure may be characterized by an electro-optic coefficient, (e.g., χ⁽²⁾, the Pockel's coefficient, or χ₍₃₎, the Kerr coefficient) having a non-zero value aligned along the direction of the electric field. For example, the leads may be coupled to a voltage source that imposes a controllable (e.g., programmable) voltage difference, thereby generating an electric field in the waveguide structure. Additionally or alternatively, a guided mode supported by the waveguide structure may have a direction of polarization aligned with the x-direction.

In some embodiments, the first electrode and the second electrode are configured as a second layer coplanar to the slab layer and disposed adjacent to a first side of the slab layer. For example, the first and second electrodes may be grown (e.g., using epitaxy or another method such as metal organic chemical vapor deposition, molecular beam epitaxy, physical vapor deposition, sol-gel, etc.) onto the first side of the slab layer, such that the first and second dielectric layers are directly coupled to the slab layer. Alternatively, in some embodiments an intervening layer may be disposed between the slab layer and the first and second dielectric layer, such that the slab layer and the first and second dielectric layers are indirectly coupled. The intervening layer may be composed of an oxide material, in some embodiments.

The first electrode and the second electrode may be separated by a gap region, e.g., gap region 243 or 343. In some embodiments, the gap region may have been etched out, and may be filled with a cladding material. In some embodiments, both the first and second electrodes may be grown as a single second layer over the slab layer, and a region may be subsequently etched out to separate the first and second electrodes. This etched region may be subsequently filled with a cladding material. Alternatively, the etched region may be left empty (i.e., may be filled with air or vacuum).

In some embodiments, the first electrode and the second electrode have a dielectric constant greater than a dielectric constant of the first material in the direction separating the first and second electrodes. The dielectric constant of the first electrode and the second electrode may be greater than the dielectric constant of the waveguide structure at a first temperature that is greater than 1 mK and/or less than 77K. In some embodiments, the first material is a transparent material having an index of refraction that is larger than an index of refraction of the first and second cladding layers. In some embodiments, a ratio between the dielectric constant of the first and second electrodes and the dielectric constant of the first material is 2 or greater.

### Transparent Electrodes

The electrical conductivity of a material is proportional to both its carrier mobility (e.g., electron mobility or hole mobility) and carrier concentration (e.g., its free electron density or hole density). Increased conductivity of the electrodes of a photonic phase shifter device may be desirable, as it may enable increased control of the device at higher frequencies and/or with reduced heating of the electrodes. However, a large free electron density of the electrodes may be undesirable, as an electrode with a large free electron density may provide a large absorptive reservoir for photons within the waveguide structure to be absorbed by the free electrons of the electrode (e.g., thereby escaping out of the waveguide structure and into the electrodes). Said another way, increasing the conductivity of the electrodes by increasing the free electron density of the material selected for the electrodes may be undesirable, as this may increase the photonic loss rate of the device.

To address these and other concerns, in some embodiments, the electrodes may be composed of a second material that is selected to have a high conductivity by virtue of its high carrier mobility, rather than due to its high carrier concentration. Advantageously, the high carrier mobility material may produce a proportionally high conductivity without introducing high photon absorption. A high carrier mobility material may exhibit desirable conductivity properties while maintaining transparency to optical modes within the waveguide by virtue of its relatively lower carrier concentration (e.g., low relative to a material with a similar conductivity and a low carrier mobility). Classical Drude theory predicts that free carrier absorption is proportional to the doping level and inversely proportional to the optical mobility. Accordingly, materials with high mobility may exhibit both decrease resistance and free carrier absorption.

For example, in some embodiments the first electrode and the second electrode are composed of a second material, where the second material has a high carrier mobility (e.g., a high electron mobility or a high hole mobility). As one example, the second material may be selected such that its electron mobility is higher than silicon. In some embodiments, the second material may be selected such that it has a band gap larger than an operating frequency of the device.

In some embodiments, the second material comprises one of gallium arsenide (GaAs), an aluminum gallium arsenide (AlGaAs)/GaAs heterostructure, an indium gallium arsenide (InGaAs)/GaAs heterostructure, zinc oxide (ZnO), zinc sulfide (ZnS), indium oxide (InO), doped silicon, a two-dimensional electron gas, or doped strontium oxide (STO). For embodiments where the second material comprises doped STO, the doped STO may be either niobium doped or lanthanum doped, or contain vacancies, among other possibilities. For example, bulk GaAs has an electron mobility of 8500 cm²/Vs, which is 6 times higher than the electron mobility of silicon. Heterostructures of InGaAs/GaAs may reach mobilities of 41000 cm²/Vs at 4 Kelvin and AlGaAs/GaAs heterostructures may reach mobilities of up to 180,000 cm²/Vs. In comparison, Si has a mobility of 1500 cm²/Vs. Doped STO may also exhibit high electron mobilities, from 10,000 cm²/Vs to 53,000 cm²/Vs, depending on carrier concentration.

For embodiments where the second material is a doped material, the doping concentration may be selected based on the absorptive properties of the resultant doped material. For example, the absorption of the doped material may be analyzed at the operating frequency or frequencies of the electro-photonic device for each of a plurality of doping concentrations, and a doping concentration may be selected which exhibits low absorption at the operating frequency or frequencies.

The following paragraphs describe various design features that differ between the architectures shown in FIGS. 7-13.

FIG. 7 illustrates an architecture where the ridge portion of the waveguide structure (251) is disposed on the bottom of the slab layer and extends into the first cladding layer (210). As illustrated in FIG. 7, the combination of the ridge portion and the slab layer has a first thickness (262) greater than a second thickness (260) of the slab layer alone (220), and the excess of the first thickness relative to the second thickness extends into the cladding layer (210) on the bottom side of the slab layer. As illustrated in FIG. 7, the first electrode (240) and the second electrode (242) are coupled to the slab layer (220) on the top side of the slab layer opposite the bottom side. Further, the first electrical contact (230) and the second electrical contact (232) are disposed on the top side of the slab layer (220). It should be noted that the terms “top” and “bottom” are used for clarity in reference to the perspective illustrated in the Figures, and do not necessarily refer to any particular orientation relative to the overall device.

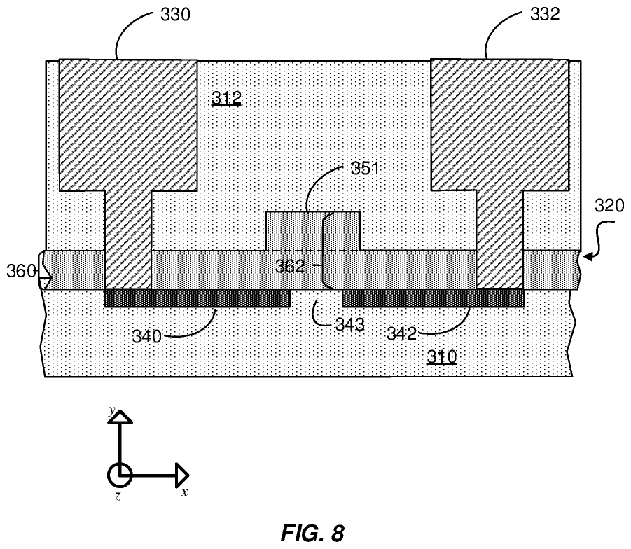

FIG. 8 illustrates an architecture where the ridge portion of the waveguide structure (351) is disposed on the top side of the slab layer and extends into a first cladding layer (312), the first electrode and the second electrode are coupled to the slab layer on the bottom side of the slab layer opposite the top side. As illustrated, the combination of the ridge portion and the slab layer has a first thickness (362) greater than a second thickness (360) of the slab layer alone (320), and the excess of the first thickness relative to the second thickness extends into the first cladding layer (312) on the top side of the slab layer (320). As illustrated in FIG. 8, the first electrode (340) and the second electrode (342) are coupled to the slab layer (320) on the bottom side of the slab layer opposite the top side. Further, the first electrical contact (330) is coupled to the first electrode (340) by penetrating through the slab layer (320) from the top side of the slab layer to the bottom side of the slab layer, and the second electrical contact (332) is coupled to the second electrode (342) by penetrating through the slab layer (320) from the top side of the slab layer to the bottom side of the slab layer.

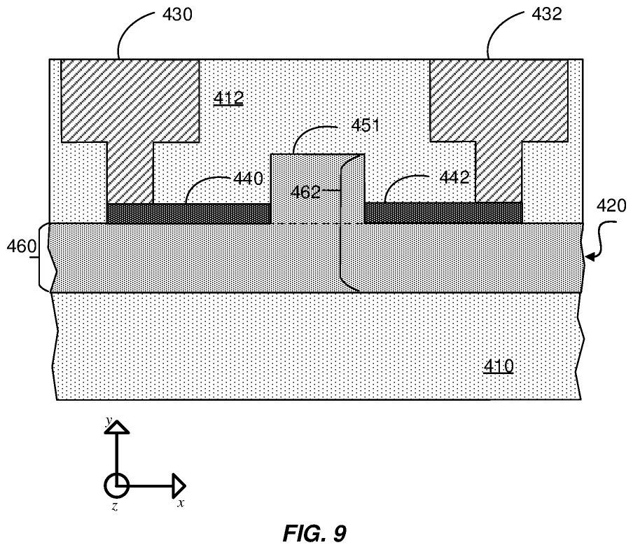

FIG. 9 illustrates an architecture where the combination of the slab layer and the ridge portion of the waveguide structure (451) has a first thickness (462) greater than a second thickness (460) of the slab layer (420), and the excess of the first thickness relative to the second thickness extends into the first cladding layer (412) on the top side of the slab layer. As illustrated in FIG. 9, the first electrode (440) and the second electrode (442) are coupled to the first material (420) on the top side of the slab layer. Further the first electrode (440) and the second electrode (442) abut the ridge portion of the waveguide structure (451).

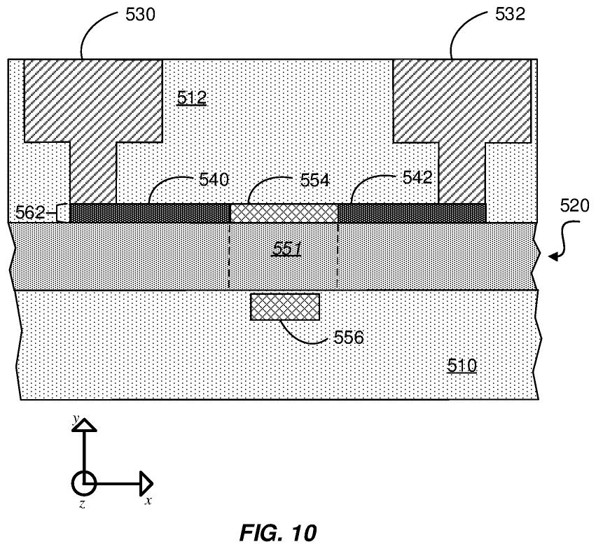

FIG. 10 illustrates an architecture where the waveguide structure includes a first strip waveguide portion (554) and a second strip waveguide portion (556), where the first and second waveguide portions are composed of a second material, and where the slab layer (520) is disposed between the first waveguide portion (554) and the second waveguide portion (556). A first electrode (540) and a second electrode (542) are disposed on the electro-optic layer (520), a first lead (530) is coupled to the first electrode, and a second lead (532) is coupled to the second electrode.

In some embodiments, the second material is silicon nitride (SiN) and the third material is silicon. In other embodiments, both the second and third materials are silicon nitride (SiN).

As illustrated in FIG. 10, the first electrode and the second electrode abut the first strip waveguide, and the first electrical electrode and the second electrode have a first thickness (562). In some embodiments, the first electrode and the second electrode comprise a second layer coplanar to the electro-optic layer and disposed adjacent to a first side of the electro-optic layer.

In some embodiments, the first and second strip waveguides are configured to concentrate center the maximum intensity portion of an optical mode within the electro-optic layer as compared to an architecture having only a strip waveguide. In other words, having only a first strip waveguide portion (554) on one side of the slab layer (520) and a cladding layer on the other side, or having only a second strip waveguide portion (556) on one side of the slab layer (520) and a cladding layer on the other side may result in a vertically offset and/or less concentrated optical mode. In some embodiments, the first strip waveguide abuts the first cladding layer and the second strip waveguide abuts the second cladding layer.

FIG. 11 illustrates a vertical waveguide architecture where the first electrode (642) is coupled to the slab layer (651) on the top side of the slab layer and the second electrode (640) is coupled to the slab layer (651) on the bottom side of the slab layer opposite the top side. In other words, the first and second electrodes are coupled to the top and bottom sides of the waveguide structure, such that the induced electric field within the waveguide structure is oriented along the y-direction.

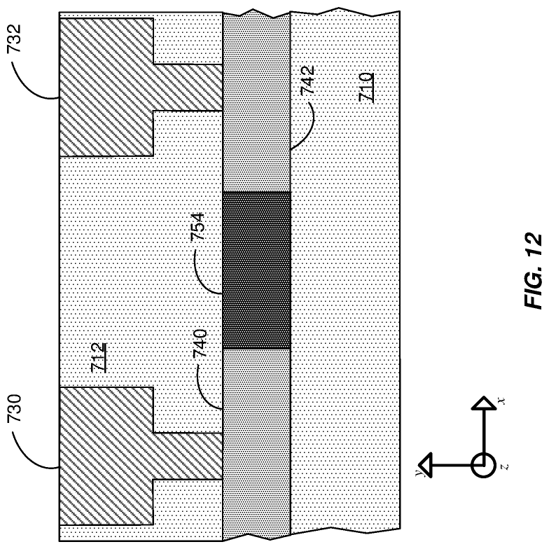

FIG. 12 illustrates a waveguide architecture where each of the first (740) and second (742) electrodes are disposed in-line with the waveguide structure (754). In other words, each of the first and second electrodes and the waveguide structure are disposed within a single layer with a single width.

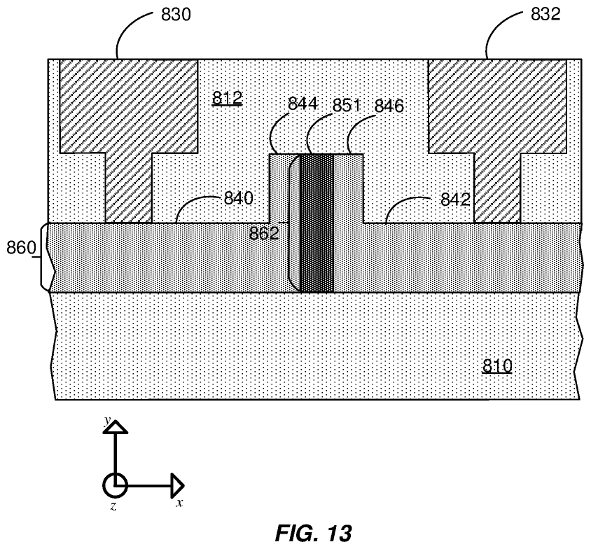

FIG. 13 illustrates a waveguide architecture where the first (840) and second (842) electrodes share a ridge-like profile with the waveguide structure (851), where the ridge-like profile extends into the first cladding layer (812). For example, the first electrode (840) may include a ridge portion (844) having a thickness (862) that is greater than a thickness (860) of the remainder of the first electrode, and the second electrode (842) may include a ridge portion (846) having a thickness (862) that is greater than the thickness (860) of the remainder of the second electrode. Further, the ridge portions of the first and second electrodes may exhibit the same thickness as the waveguide structure (851).

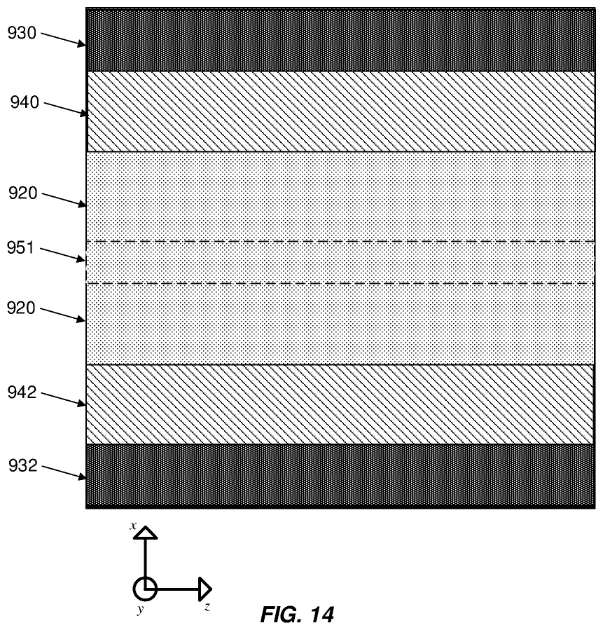

FIG. 14 is a top-down view of a photonic phase-shifter architecture, according to some embodiments. As illustrated, the phase-shifter may include first (930) and second (932) leads, first (940) and second (942) electrodes, a slab (e.g., waveguide) layer (920), and a ridge portion of the waveguide structure (951).

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising.” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting” or “in accordance with a determination that.” depending on the context.

The foregoing description, for purpose of explanation, has been described with reference to specific embodiments. However, the illustrative discussions above are not intended to be exhaustive or to limit the scope of the claims to the precise forms disclosed. Many modifications and variations are possible in view of the above teachings. The embodiments were chosen in order to best explain the principles underlying the claims and their practical applications, to thereby enable others skilled in the art to best use the embodiments with various modifications as are suited to the particular uses contemplated.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method, comprising:
depositing a crystalline magnesium oxide (MgO) seed layer directly on an amorphous insulating cladding layer by a physical vapor deposition (PVD) process; and
depositing a crystalline electro-optic layer directly on the crystalline MgO seed layer.

2. The method of claim 1, wherein the crystalline electro-optic layer is between 50 nanometers (nm) and 500 nm in thickness, the crystalline MgO seed layer is between 1 nm and 20 nm in thickness, and the amorphous insulating cladding layer is between 1 micrometer (μm) and 10 μm in thickness.

3. The method of claim 1, wherein the amorphous insulating cladding layer comprises silicon oxide, silicon nitride, silicon oxynitride or tantalum oxide.

4. The method of claim 1, wherein the crystalline electro-optic layer comprises a ferroelectric waveguide layer.

5. The method of claim 4, wherein the crystalline electro-optic layer comprises barium titanate (BTO) and crystalline MgO seed layer is formed by electron beam evaporation or ion beam-assisted deposition.

6. The method of claim 1, wherein the crystalline electro-optic layer comprises one of:
strontium titanate (STO);
barium strontium titanate (BST);
hafnium oxide;
lithium niobate;
zirconium oxide;
titanium oxide;
graphene oxide;
tantalum oxide;
lead zirconium titanate (PZT);
lead lanthanum zirconium titanate (PLZT);
strontium barium niobate (SBN); or
aluminum oxide.

7. The method of claim 1, further comprising forming a first waveguide embedded within the amorphous insulating cladding layer.

8. The method of claim 1, further comprising:
etching the electro-optic layer to produce a ridge structure; and
depositing an additional insulating cladding layer on the etched electro-optic layer.

9. The method of claim 8, further comprising forming a second waveguide embedded within the additional insulating cladding layer.

10. The method of claim 8, further comprising forming doped or vacancy containing strontium titanate (STO) electrodes in contact with the electro-optic layer and forming electrically conductive leads in contact with the STO electrodes.

11. A device, comprising
a crystalline magnesium oxide (MgO) seed layer located directly on an amorphous insulating cladding layer; and
a crystalline electro-optic layer located directly on the crystalline MgO seed layer via a second PVD process.

12. The device of claim 11, wherein the crystalline electro-optic layer is between 50 nanometers (nm) and 500 nm in thickness, the crystalline MgO seed layer is between 1 nm and 20 nm in thickness, and the amorphous insulating cladding layer is between 1 micrometer (μm) and 10 μm in thickness.

13. The device of claim 11, wherein the amorphous insulating cladding layer comprises silicon oxide, silicon nitride, silicon oxynitride or tantalum oxide.

14. The device of claim 11, wherein the crystalline electro-optic layer comprises a ferroelectric waveguide layer.

15. The device of claim 14, wherein the crystalline electro-optic layer comprises barium titanate (BTO).

16. The device of claim 11, wherein the crystalline electro-optic layer comprises one of:
strontium titanate (STO);
barium strontium titanate (BST);
hafnium oxide;
lithium niobate;
zirconium oxide;
titanium oxide;
graphene oxide;
tantalum oxide;
lead zirconium titanate (PZT);
lead lanthanum zirconium titanate (PLZT);
strontium barium niobate (SBN); or
aluminum oxide.

17. The device of claim 11, further comprising a first waveguide embedded within the amorphous insulating cladding layer.

18. The device of claim 11, further comprising:
a ridge structure located in the electro-optic layer; and
an additional insulating cladding layer located on the electro-optic layer.

19. The device of claim 18, further comprising a second waveguide embedded within the additional insulating cladding layer.

20. The device of claim 18, further comprising forming doped or vacancy containing strontium titanium oxide (STO) electrodes in contact with the electro-optic layer and forming electrically conductive leads in contact with the STO electrodes, wherein the device comprises an electro-optic switch or modulator.
